(19) United States
(12) Patent Application Publication
(10) Pub. No.: US 2017/0150088 A1
(43) Pub. Date: May 25, 2017

(54) DISPLAY DEVICE AND TELEVISION RECEIVER

(71) Applicant: Sharp Kabushiki Kaisha, Sakai City, Osaka (JP)

(72) Inventor: Takumi NIINA, Sakai City (JP)

(73) Assignee: Sharp Kabushiki Kaisha, Sakai City, Osaka (JP)

(21) Appl. No.: 15/316,593

(22) PCT Filed: May 28, 2015
(86) PCT No.: PCT/JP2015/065427

§ 371 Date: Dec. 6, 2016

(30) Foreign Application Priority Data
Jun. 6, 2014 (JP) 2014-117931

(51) Int. Cl. H04N 5/64; H05K 5/02; H04N 5/44

(52) U.S. Cl. CPC H04N 5/64; H04N 5/44; H05K 5/0234; G02F 2001/133302

(57) ABSTRACT

A display device for which it is possible to easily set a desired inclination angle in each model and it allows commonality of a fixing structure of a holding body having a display portion and a stand without lowering product outer appearance quality, and a television receiver that is provided with the display device. A chassis which holds the display portion that includes a display panel which displays a video, a stand which supports the chassis, and a fixture for attaching the stand to the chassis are provided. The fixture has a screw insertion hole, and the chassis has a screw fastening portion that is provided with a hole which has a female screw and a seat that is provided around the hole. The height of the screw fastening portion is different in the vertical direction of the chassis.

### CROSS-REFERENCE TO RELATED APPLICATIONS

This application is the national phase under 35 U. S. C. §371 of PCT International Application No. PCT/JP2015/065427 which has an International filing date of May 28, 2015 and designated the United States of America.

### FIELD

The present disclosure relates to a display device which is provided with a display portion that includes a display panel which displays a video, a holding body that holds the display portion, a stand which supports the holding body, and a fixture for attaching the stand to the holding body, and a television receiver that is provided with the display device.

### BACKGROUND

For example, a television receiver (hereinafter referred to as TV receiver) such as a liquid crystal television receiver is provided with a display panel that displays a video on a front surface side, a display module (display portion) that has a backlight that radiates light on the display panel, a front cabinet and a rear cabinet made from synthetic resin that accommodate the display module, and a stand. The entirety of the display module has a substantially horizontally long rectangular shape, and is accommodated in the front cabinet and the rear cabinet in a vertical posture.

The stand is provided with a foot portion and a support shaft that extends from the foot portion. The support shaft is fixed in a chassis that accommodates the backlight using a fixture, and the chassis is supported on the stand.

As an example of the fixture, there is provided a fixture including a main body, which for example, has a cross section in a U shape, and an abutting plate portion that is provided on both edge portions of the main body and has an elongated rectangular shape. A screw insertion hole is provided in the abutting plate portion. A screw fastening portion, which is made from a hole that has a female screw and a seat that is provided around the hole, is provided in the chassis, and in a state in which the screw insertion hole matches the female screw, the fixture is configured to be attached to the chassis by the abutting plate portion abutting the chassis and the screw being inserted through and screwed into the female screw.

In recent years, it is often the case that a chassis and a fixture in a TV receiver are made common in order to reduce costs.

In this case, variation of components is widened using the same chassis and fixture by a providing a plurality of the screw fastening portions such that it is possible to provide, for example, the fixture at a plurality of locations in a lateral direction of the chassis, that is, in the lateral direction of the chassis, and attaching the stand at different positions in each model.

However, in a case where the stands are different and the inclinations and the like of the support shaft of, for example, the stand are different, when the screw fastening portion is provided uniformly in the chassis, after attachment of the stand, the inclination of the display module is different according to the TV receiver and thus there is a problem in that product outer appearance quality worsens.

Therefore, a technique is desirable in which an inclination of the display module is possible in the same manner even in a case where the model is different.

A structure of the TV receiver in Japanese Unexamined Patent Application Publication No. 2013-78131 is given as the structure in which an inclination angle of the same display module is changed. In the TV receiver, there is an attaching portion on the lower end portion of the rear surface of the rear cabinet. The stand has a plate shape base portion, a fixing portion that has an abutting surface which abuts the attaching portion and that fixes a position of the display module with respect to the base portion by causing the attaching portion to abut the abutting surface, and an angle adjustment portion that is provided on the base portion, is interposed between the lower surface of the front cabinet and the base portion, and supports the display module in an inclined state. In the TV receiver, the inclination angle of the display module is changed by changing the height of the angle adjustment portion (gap between the lower surface of the front cabinet and the base portion). However, in order to obtain a desired inclination angle in each TV receiver, it is necessary to prepare the stand which is provided with the fixing portion that has the abutting surface which has the predetermined inclination angle and the angle adjustment portion that has the predetermined height, and there is a problem in that a setting method of the inclination angle is complicated.

### SUMMARY

The present disclosure is carried out in consideration of the above circumstances, and the object thereof is to provide a display device for which it is possible to easily set a desired inclination angle in each model and it allows commonality of a fixing structure of a holding body having a display portion and a stand without lowering product outer appearance quality and a TV receiver that is provided with the display device.

A display device according to an aspect of the present disclosure is provided with a display portion that includes a display panel which displays a video; a holding body that holds the display portion; a stand that supports the holding body; a fixture for attaching the stand to the holding body; and a plurality of fixing portions that are interposed between the fixture and the holding body and fix the fixture to the holding body, in which in a case where at least one of the fixing portions fixes the fixture to the holding body, the holding body has a predetermined angle with respect to the fixture.

In the display device according to the present disclosure, lengths of the fixing portions in a direction in which the fixture and the holding body face each other are different.

In the display device according to the present disclosure, a plurality of the fixing portions are arranged side by side in a vertical direction of the display portion, and the lengths gradually change between the fixing portions.

In the display device according to the present disclosure, a plurality of the fixing portions are arranged side by side in a lateral direction of the display portion, and the degrees of difference of the lengths of the fixing portions in the vertical direction are different in the lateral direction.

In the display device according to the present disclosure, the fixing portions are provided in the holding body, each of the fixing portions has a hole that has a female screw and a seat that is provided around the hole, the height of the seat is different in at least one of the fixing portions, and the fixture has a screw insertion hole for a male screw to be inserted through and screwed into the female screw.

In the display device according to the present disclosure, the fixing portions are provided in the holding body, each of the fixing portions has a pin and a seat that is provided around the pin, the height of the seat is different in at least one of the fixing portions, and the fixture has a pin insertion hole into which the pin is inserted and positionally aligned.

In the display device according to the present disclosure, the fixing portions are provided in the fixture, each of the fixing portions has the screw insertion hole and the seat that is provided around the screw insertion hole, the height of the seat is different in at least one of the fixing portions, and the female screw into which a screw that is inserted into the screw insertion hole is screwed is provided in the holding body.

A television receiver according to the present disclosure is provided with any one of the display devices described above, and a receiver that receives a television broadcast, in which a video is displayed on the display device based on the television broadcast that is received by the receiver.

According to the display device of the present disclosure, since the fixture for attaching the stand to the holding body of the display portion and the plurality of fixing portions that are interposed between the fixture and the holding body and fix the fixture to the holding body are provided, and lengths of at least one of the fixing portions in a direction in which the fixture and the holding body face each other are configured to be different, it is possible to easily set the desired inclination angle in each model, and it allows commonality of the fixing structure of the holding body having the display portion and the stand. Then, the outer appearance quality of the display device is favorable.

The above and further objects and features will more fully be apparent from the following detailed description with accompanying drawings.

### BRIEF DESCRIPTION OF THE DRAWINGS

FIG. 1 is an outer appearance perspective view of a TV receiver according to Embodiment 1 of the present disclosure.

FIG. 2 is a perspective view illustrating a state in which the TV receiver is viewed from a rear side.

FIG. 3 is a rear surface view illustrating a state in which a rear cabinet of the TV receiver is removed.

FIG. 4 is an enlarged view of a left lower part in FIG. 3.

FIG. 5 is a perspective view illustrating a state in which the rear cabinet of the TV receiver is removed.

FIG. 6 is a perspective view illustrating a state in which a fixture in FIG. 5 is removed.

FIG. 7 is an enlarged view of a left lower part in FIG. 6.

FIG. 8A is a diagram for describing a method in which an inclination angle of a chassis is adjusted by changing a height of a screw fastening portion.

FIG. 8B is a diagram for describing a method in which the inclination angle of the chassis is adjusted by changing the height of the screw fastening portion.

FIG. 9 is a diagram for describing a method in which the inclination angle of the chassis is adjusted using different stands for the same chassis.

FIG. 10A is a diagram for describing a method in which the inclination angle of the chassis is adjusted by changing the height of a pin fastening portion according to Embodiment 2 of the present disclosure.

FIG. 10B is a diagram for describing a method in which the inclination angle of the chassis is adjusted by changing the height of the pin fastening portion according to Embodiment 2 of the present disclosure.

FIG. 11 is a perspective view illustrating a state in which a fixture according to Embodiment 3 of the present disclosure is viewed from the rear side.

FIG. 12A is a diagram for describing a method in which the inclination angle of the chassis is adjusted by changing the height of a seat.

FIG. 12B is a diagram for describing a method in which the inclination angle of the chassis is adjusted by changing the height of the seat.

FIG. 13 is a perspective view illustrating a state in which a fixture according to Embodiment 4 of the present disclosure is viewed from the rear side.

FIG. 14A is a diagram for describing a method in which the inclination angle of the chassis is adjusted by changing the height of the seat.

FIG. 14B is a diagram for describing a method in which the inclination angle of the chassis is adjusted by changing the height of the seat.

FIG. 15 is a diagram for describing a method in which the inclination angle of the chassis is adjusted by inclining a part on the lower side of the bottom surface of the chassis according to Embodiment 5 of the present disclosure.

FIG. 16 is a diagram for describing a method in which the inclination angle of the chassis is adjusted by changing the height of the fixture according to Embodiment 6 of the present disclosure.

### DETAILED DESCRIPTION

Embodiments of the present disclosure will be described below in detail with reference to the drawings.

### Embodiment 1

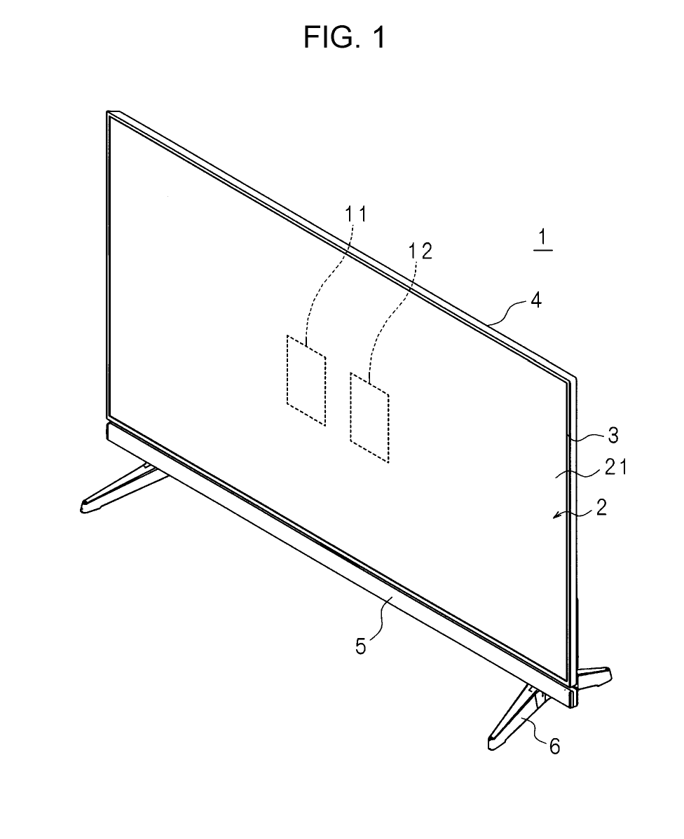

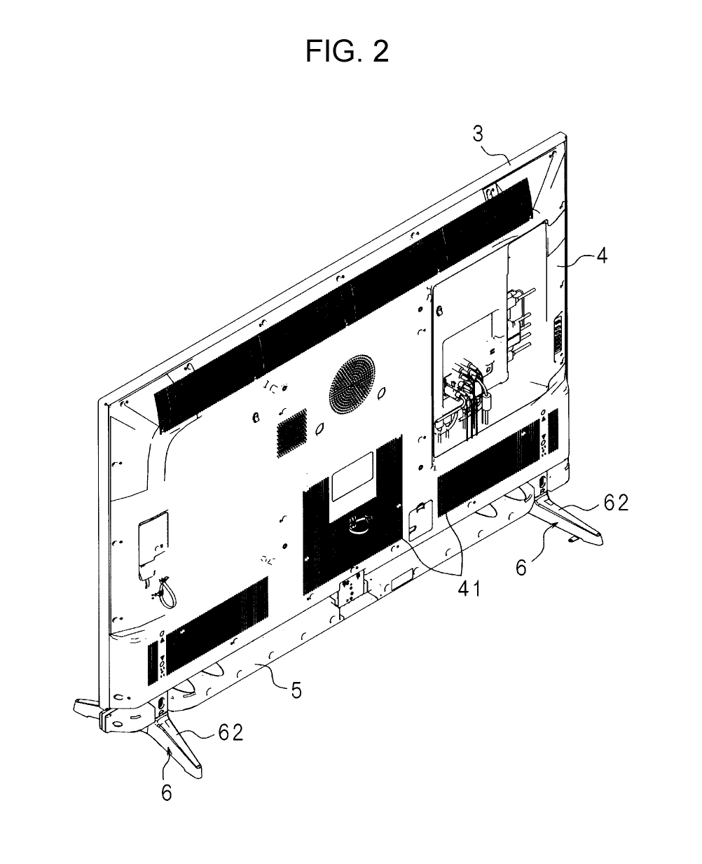

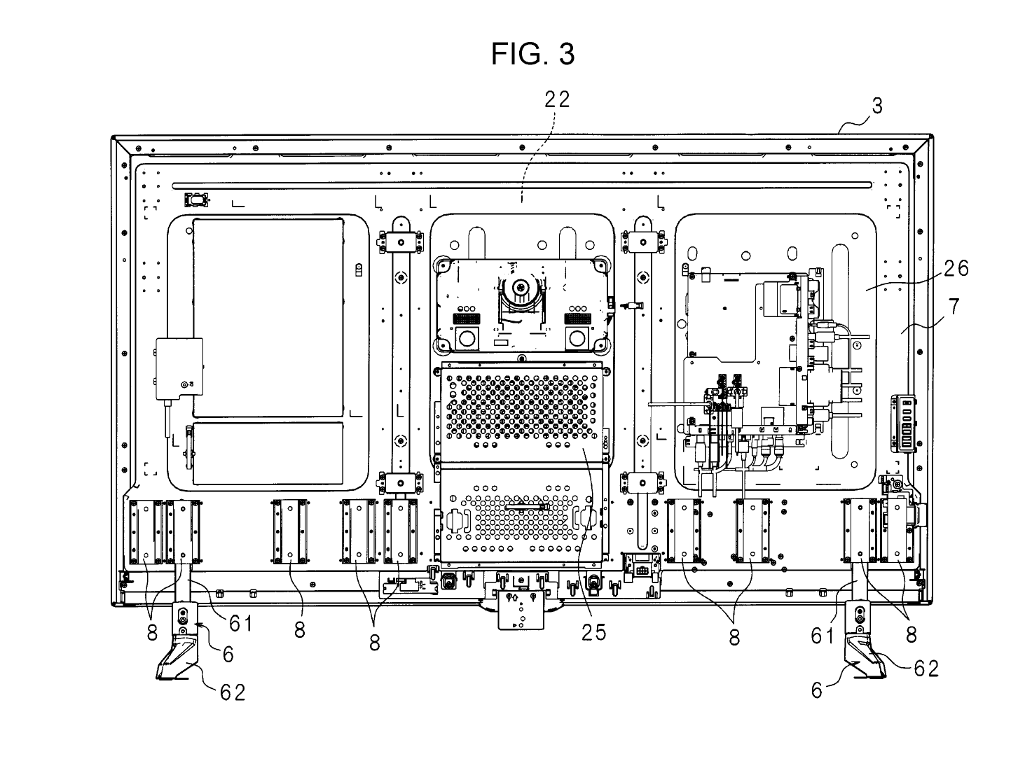

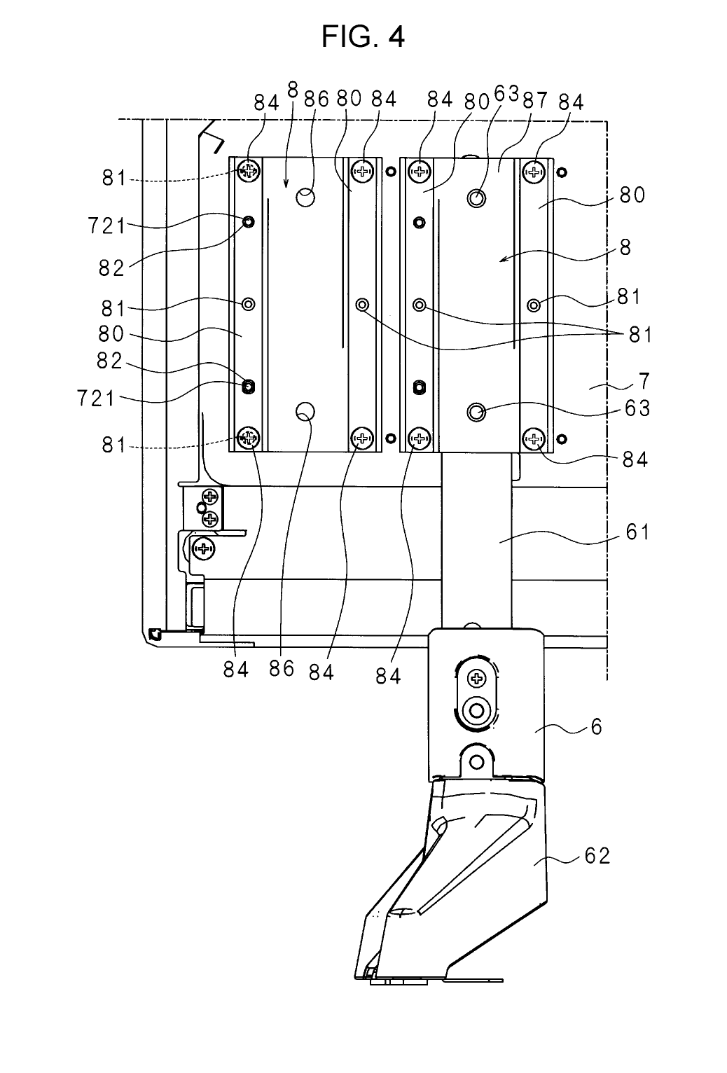

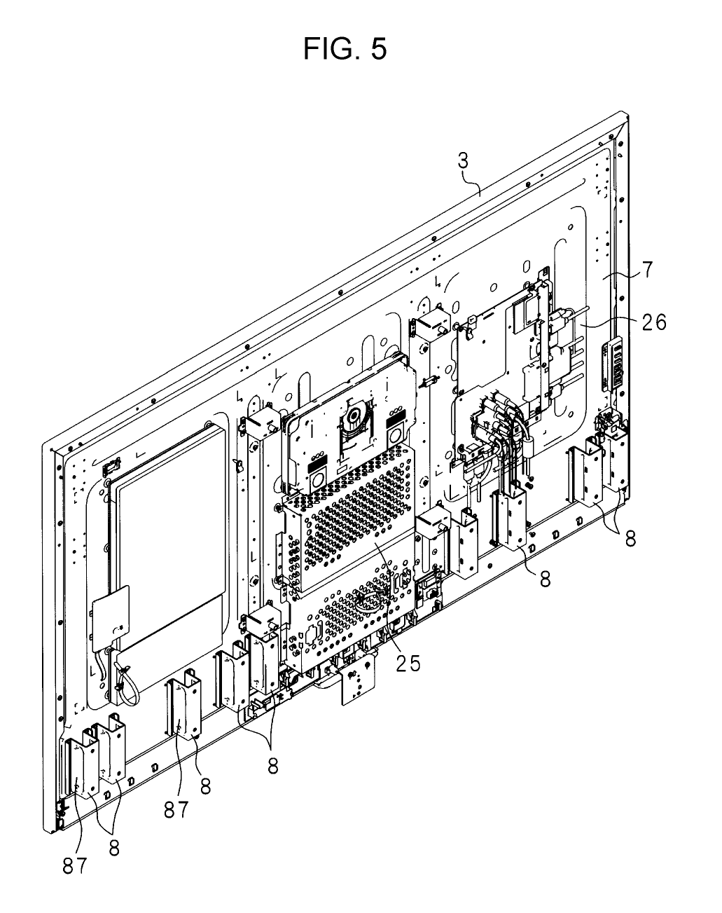

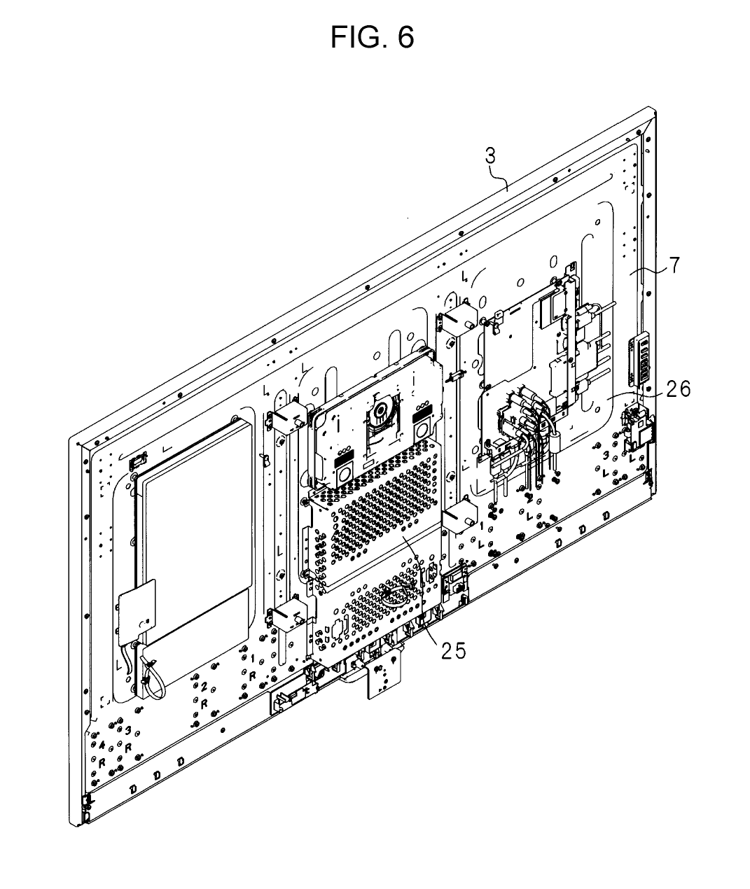

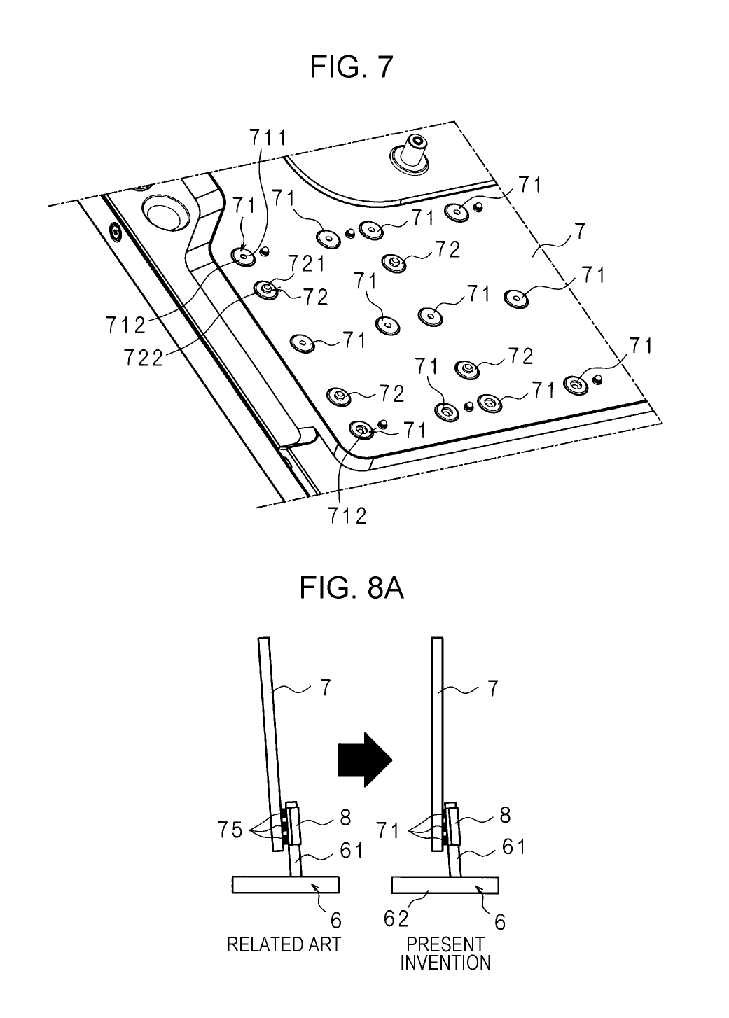

FIG. 1 is an outer appearance perspective view of a television receiver (TV receiver) 1 according to the present disclosure, FIG. 2 is a perspective view illustrating a state in which the TV receiver 1 is viewed from a rear side, FIG. 3 is a rear surface view illustrating a state in which a rear cabinet of the TV receiver 1 is removed, FIG. 4 is an enlarged view of a left lower part in FIG. 3, FIG. 5 is a perspective view illustrating a state in which the rear cabinet of the TV receiver 1 is removed, FIG. 6 is a perspective view illustrating a state in which a fixture in FIG. 5 is removed, and FIG. 7 is an enlarged view of a left lower part in FIG. 6.

The TV receiver 1 is provided with a display module 2 that has a display panel 21 and a backlight 22, a front cabinet 3 and a rear cabinet 4 made from synthetic resin that accommodate the display module 2, a speaker box 5 in which a plurality of speakers are built, two stands 6, a tuner 11 that receives a broadcast wave from an antenna (not illustrated), and a decoder 12 that decodes an encoded broadcast wave. The entirety of the display module 2 has a substantially horizontally long rectangular shape, and is accommodated in the front cabinet 3 and the rear cabinet 4 in a vertical posture.

The front cabinet 3 is a rectangular frame.

The rear cabinet 4 is a box shape so as to cover a side surface and a rear surface of the display module 2. A plurality of heat dissipation slits 41 are provided in the rear cabinet 4.

The stand 6 is provided with a foot portion 62 and a support shaft 61 that extends from the foot portion 62 to the upper side. Then, female screws 63 and 63 are provided at two locations vertically on the support shaft 61 (refer to FIG. 4).

The backlight 22 of the display module 2 has an optical sheet, a light guide plate, and an LED substrate (described above, not illustrated here).

The backlight 22 is accommodated in the chassis 7 that is a substantial box shape in which the display panel 21 side is open.

The light guide plate is a rectangular plate shape, and has a main surface that faces the display panel 21 side, a rear surface that faces the chassis 7 on the opposite surface from the main surface, a pair of long side surfaces, and a pair of short side surfaces. In a case where the backlight 22 has an edge light method, one long side surface functions as a light incidence surface for introducing light into the light guide plate, and light that is introduced from the long side surface into the light guide plate is emitted from the main surface of the light guide plate toward the display panel 21 side.

The optical sheet is a sheet group that includes a diffusion sheet, a lens sheet, a DBEF sheet (reflective polarizing sheet), and the like, and is mounted on the main surface of the light guide plate. Then, diffusion, condensing, and the like of light that is emitted from the main surface of the light guide plate is performed using the optical sheet.

The LED substrate generates light that is introduced into the light guide plate, and is disposed on the long side surface side of the light guide plate. A plurality of LEDs are mounted on a horizontal plane of the substrate main body of the LED substrate. The LED substrate extends along the long side of the main surface of the light guide plate and the plurality of LEDs are disposed so as to face the long side surface of the light guide plate.

The display panel 21 has a liquid crystal layer, a pair of glass substrates, and a polarizing plate. The pair of glass substrates interpose a sealing material and are bonded to each other, and the liquid crystal layer is enclosed therebetween. Then, the polarizing plate is respectively disposed on the surface on the opposite side from the liquid crystal layer side of the pair of glass substrates.

As shown in FIG. 3, a main substrate 25 which is provided with the tuner 11, a decoder 12, a CPU, and the like is provided in a center portion of the rear surface of the chassis 7, and a terminal panel 26 that has an antenna input terminal, a USB (registered trademark) terminal, a headphone terminal, a B-CAS card slot, and the like is provided adjacent to the main substrate 25.

Then, fixtures 8 and 8 are provided in a long side part on the lower side of the chassis 7. Note that, FIG. 3 illustrates a state in which a plurality of fixtures 8, 8, and the like are provided along the long side part on the lower side of the chassis 7, but here, illustrates that it is possible to attach the fixture 8 to the desired position corresponding to a row of the screw fastening portions 71 of the chassis 7 which will be described later, and two fixtures 8 are attached to the actual product.

As shown in FIGS. 4 and 5, the fixture 8 is made from metal, the cross section is a U shape, and the fixture 8 has an insertion portion 87 that extends in the vertical direction of the chassis 7 and abutting plate portions 80 and 80 that are provided on both edge portions of the insertion portion 87 in the width direction and are elongated rectangular shapes. Then, screw insertion holes 86 and 86 are provided vertically at two locations in a center portion of the insertion portion 87.

A screw insertion hole 81, a pin insertion hole 82, the screw insertion hole 81, the pin insertion hole 82, and the screw insertion hole 81 are provided in order from above on one abutting plate portion 80. The screw insertion hole 81, the screw insertion hole 81, and the screw insertion hole 81 are provided in order from above on the other abutting plate portion 80 of the fixture 8.

As shown in FIG. 7, the screw fastening portion 71, the pin fastening portion 72, the screw fastening portion 71, the pin fastening portion 72, and the screw fastening portion 71 are provided in order from above on the left end part on the lower portion of the chassis 7 corresponding to the screw insertion hole 81, the pin insertion hole 82, the screw insertion hole 81, the pin insertion hole 82, and the screw insertion hole 81 of the one abutting plate portion 80.

The screw fastening portion 71 has a hole 711 that has a female screw and a seat 712 with a disc shape that is provided around the hole 711.

The pin fastening portion 72 has a pin 721 and a seat 722 with a disc shape that is provided around the pin 721.

The screw fastening portion 71, the screw fastening portion 71, and the screw fastening portion 71 on one row are provided in order from above corresponding to the screw insertion hole 81, the screw insertion hole 81, and the screw insertion hole 81 of the other abutting plate portion 80 so as to be adjacent to the row that includes the screw fastening portions 71.

A plurality of sets each of which is made from the row of the screw fastening portion 71, the pin fastening portion 72, the screw fastening portion 71, the pin fastening portion 72, and the screw fastening portion 71 and the row of the screw fastening portion 71, the screw fastening portion 71, and the screw fastening portion 71 are arranged side by side in the chassis 7 in the lateral direction of the chassis 7.

As shown in FIG. 4, the one abutting plate portion 80 is disposed on a row of the screw fastening portions 71 on the leftmost end of the chassis 7 in a state in which each pin 721 is inserted into each pin insertion hole 82, and each screw 84 is inserted into each screw insertion hole 81 and screwed in each female screw of each hole 711. The other abutting plate portion 80 is disposed on a row of the screw fastening portions 71 of the second row from the left of the chassis 7, and each screw 84 is inserted into each screw insertion hole 81 and screwed in each female screw of each hole 711. Thereby, the fixture 8 is fixed in the chassis 7.

Another fixture 8 is fixed in the same manner as described above adjacent to the leftmost end fixture 8. In the fixture 8, in a state in which the support shaft 61 of the stand 6 is inserted into the insertion portion 87 and the female screw 63 matches the screw insertion hole 86, the screw is inserted into the screw insertion hole 86 from the outside of the rear cabinet 4 and screwed with the female screw 63. Thereby, the stand 6 is fixed in the chassis 7.

In the present embodiment, the height is different of at least one of the seats 712 of a plurality of screw fastening portions 71 which are provided in the vertical direction and the lateral direction of the chassis 7.

Accordingly, in a case where the stand 6 is used that is different in each model, it is possible to set the angle between the abutting plate portion 80 of the fixture 8 (support shaft 61 of the stand 6) and the chassis 7 to the desired angle, and it is possible to easily set the inclination angle of the chassis 7 (display module 2) to the desired angle.

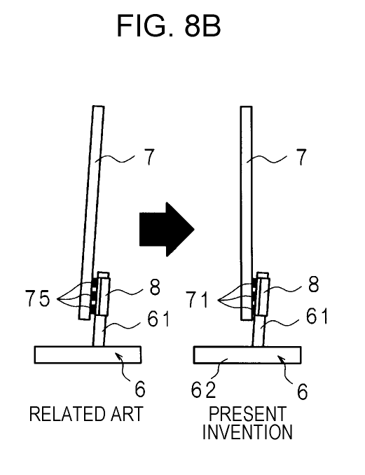

FIGS. 8A and 8B are diagrams for describing a method in which the inclination angle of the chassis 7 is adjusted by changing the height of the screw fastening portion 71.

As shown in FIG. 8A, in a case where the support shaft 61 of the stand 6 is a forward-bent posture, and in a case where the heights of the pin fastening portions 75 are the same as in a conventional example, the chassis 7 is also at the forward-bent posture.

In the embodiment of the present disclosure, the vertical direction (short hand direction) of the chassis 7 substantially matches a direction perpendicular to the foot portion 62 by the height (of the seat 712) of the screw fastening portion 71 at the lower side being higher than at the upper side, that is, by configuring such that the heights of the seats 712 in the vertical direction (up and down direction) are gradually increased from up to down.

In a case where the support shaft 61 is provided so as to substantially match the direction perpendicular to the foot portion 62, it is possible to set the chassis 7 to a rearward-bent posture by the height of the seat 712 of the screw fastening portion 71 at the lower side being higher than at the upper side, that is, by configuring such that the heights of the seats 712 in the vertical direction are gradually increased from up to down.

The following is given as an example of the relationship between the difference of the heights of two seats 712 lined up in the vertical direction and an adjustment amount of the angle.

Relationship between Difference of Heights of Seats 712 and Adjustment Amount of Angle

| Difference of Heights | Adjustment Amount |
|---|---|
| of Seats 712 | of Angle |
| 0.5 mm | 0.4 degrees |
| 1.0 mm | 0.8 degrees |
| 1.5 mm | 1.2 degrees |

The gap between seats 712 is approximately 70 mm.

As shown in FIG. 8B, in a case where the support shaft 61 of the stand 6 is at the rearward-bent posture, and in a case where the heights of the pin fastening portions 75 are the same as in a conventional example, the chassis 7 is at the rearward-bent posture.

In the embodiment of the present disclosure, the vertical direction of the chassis 7 substantially matches the direction perpendicular to the foot portion 62 by the height of the seat 712 of the screw fastening portion 71 at the upper side being higher than at the lower side, that is, by configuring such that the heights of the seats 712 in the vertical direction (up and down direction) are gradually decreased from up to down.

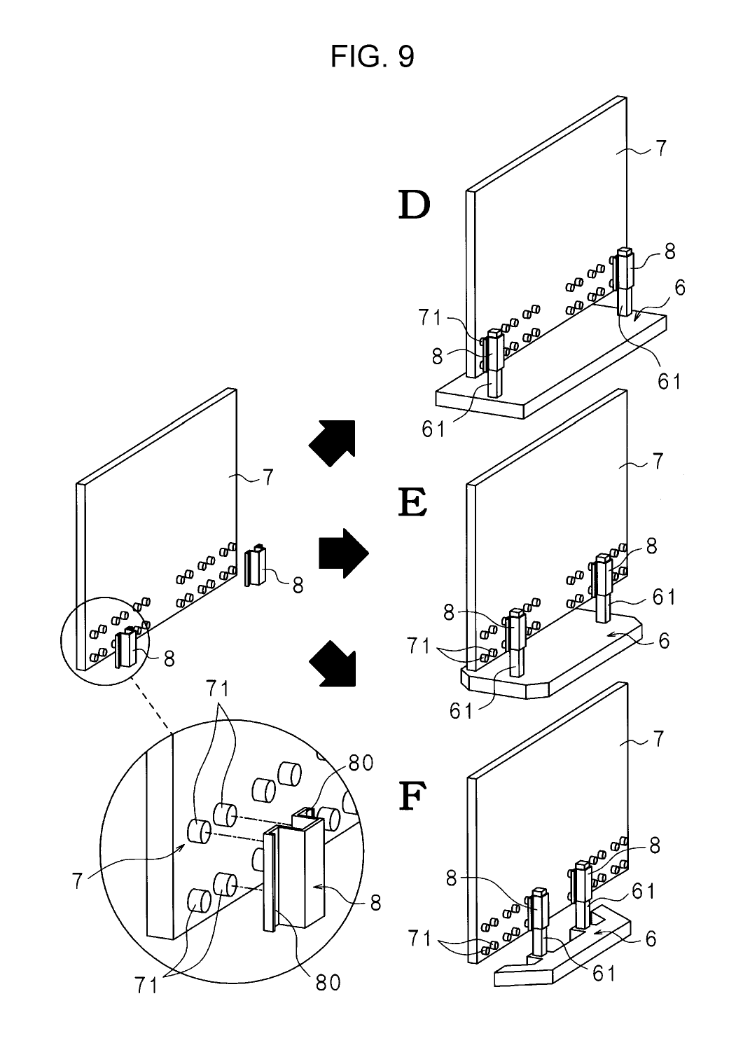

FIG. 9 is a diagram for describing a method in which the inclination angle of the chassis 7 is adjusted using the different stands 6 for the same chassis 7. Note that, in FIG. 9, the number of screw fastening portions 71 in the vertical direction is two.

Three stands 6 have different gaps between the two support shafts 61 and 61. As shown in FIG. 9, the gaps between the support shafts 61 and 61 widen in order of F, E, and D

As described above, in a case where the support shaft 61 is provided so as to substantially match the direction perpendicular to the foot portion 62, it is possible to set the chassis 7 to a rearward-bent posture by the height (of the seat 712) of the screw fastening portion 71 at the lower side being higher than at the upper side.

A plurality of the seats 712 of the screw fastening portion 71 are arranged side by side in the lateral direction, the difference of the heights between the seats 712 in one set lined up in the vertical direction is different from a difference of heights between the seats 712 in another set in the lateral direction, and the difference at the center portion is larger than the difference at both end portions.

In this case, it is possible to increase the inclination angle in order of D, E, and F.

As above, it is possible to change the inclination angle of the chassis 7 by gradually changing the height of the seats 712 in the vertical direction of the chassis 7.

In addition, it is possible to fix the stand 6 that has the same of different inclination angle of the support shaft 61 at the desired position of the chassis 7 and set the inclination angle of the chassis 7 to the desired angle by changing the degree of difference of the heights of the upper and lower seats 712 in the lateral direction of the chassis 7.

Accordingly, it allows commonality of the fixing structure having the chassis 7 and the stand 6 without lowering the product outer appearance quality.

### Embodiment 2

In Embodiment 2 of the present disclosure, the inclination angle of the chassis 7 is adjusted by changing the height of the seat 722 of the pin fastening portion 72 without changing the height of the seat 712 of the screw fastening portion 71 in the manner of Embodiment 1.

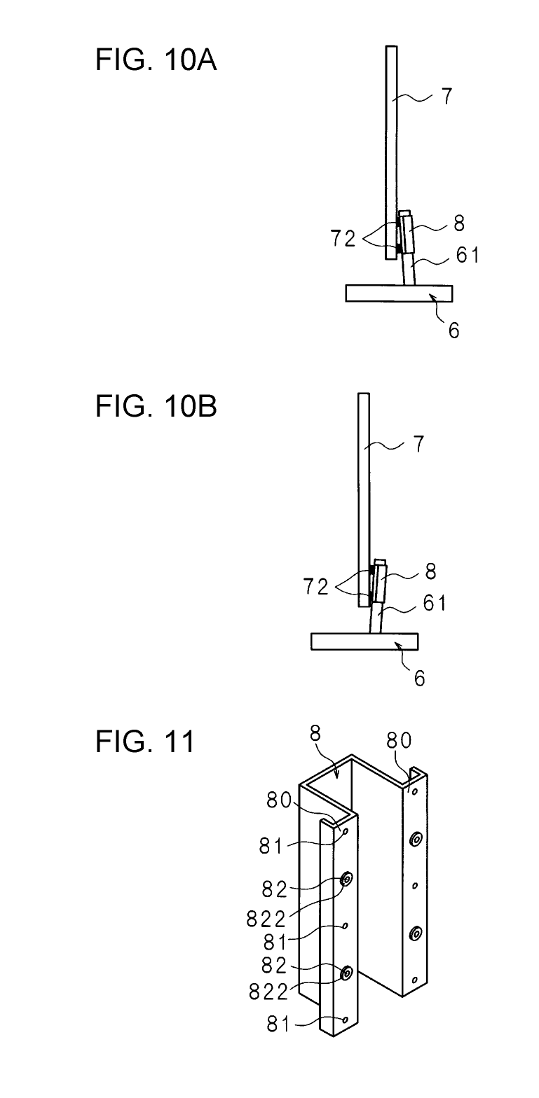

FIGS. 10A and 10B are diagrams for describing a method in which the inclination angle of the chassis 7 is adjusted by changing the height of the pin fastening portion 72.

As shown in FIG. 10A, in a case where the support shaft 61 of the stand 6 is at the forward-bent posture, the vertical direction of the chassis 7 substantially matches the direction perpendicular to the foot portion 62 by the height of the seat 722 of the pin fastening portion 72 at the lower side being higher than at the upper side, that is, by configuring such that the heights of the seats 722 in the vertical direction (up and down direction) are gradually increased from up to down.

In a case where the support shaft 61 is provided so as to substantially match the perpendicular direction, it is possible to set the chassis 7 to a rearward-bent posture by the height of the seat 722 of the pin fastening portion 72 at the lower side being higher than at the upper side, that is, by configuring such that the heights of the seats 722 in the vertical direction are gradually increased from up to down.

As shown in FIG. 10B, in a case where the support shaft 61 of the stand 6 is at the rearward-bent posture, the vertical direction of the chassis 7 substantially matches the direction perpendicular to the foot portion 62 by the height of the seat 722 of the pin fastening portion 72 at the upper side being higher than at the lower side, that is, by configuring such that the heights of the seats 722 in the vertical direction (up and down direction) are gradually decreased from up to down.

As above, it is possible to change the inclination angle of the chassis 7 by gradually changing the height of the seats 722 in the vertical direction of the chassis 7.

Then, it is possible to fix various stands 6 at the desired positions of the chassis 7 and set the inclination angle of the chassis 7 to the desired angle by changing the degree of difference of the heights of the upper and lower seats 722 in the lateral direction of the chassis 7.

### Embodiment 3

In Embodiment 3 of the present disclosure, the inclination angle of the chassis 7 is adjusted at the fixture 8 side and not at the chassis 7 side in the manner of Embodiment 1.

FIG. 11 is a perspective view illustrating a state in which the fixture 8 according to Embodiment 3 is viewed from the rear side. As shown in FIG. 11, the fixture 8 of the present embodiment is provided with the screw insertion hole 81, the pin insertion hole 82, the screw insertion hole 81, the pin insertion hole 82, and the screw insertion hole 81 on both abutting plate portions 80. Then, a seat 822 with a disc shape is provided around the pin insertion hole 82.

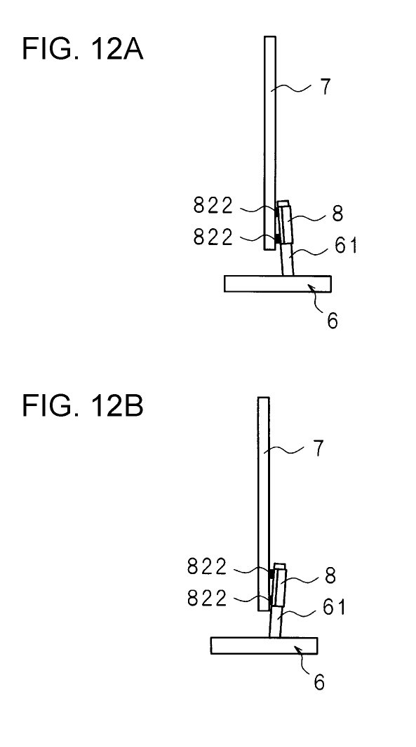

FIGS. 12A and 12B are diagrams for describing a method in which the inclination angle of the chassis 7 is adjusted by changing the height of the seat 822.

As shown in FIG. 12A, in a case where the support shaft 61 of the stand 6 is at the forward-bent posture, the vertical direction of the chassis 7 substantially matches the direction perpendicular to the foot portion 62 by the height of the seat 822 at the lower side being higher than at the upper side, that is, by configuring such that the heights of the seats 822 in the vertical direction (up and down direction) are gradually increased from up to down.

In a case where the support shaft 61 is provided so as to substantially match the perpendicular direction, it is possible to set the chassis 7 to a rearward-bent posture by the height of the seat 822 at the lower side being higher than at the upper side.

As shown in FIG. 12B, in a case where the support shaft 61 of the stand 6 is at the rearward-bent posture, the vertical direction of the chassis 7 substantially matches the direction perpendicular to the foot portion 62 by the height of the seat 822 at the upper side being higher than at the lower side, that is, by configuring such that the heights of the seats 822 in the vertical direction (up and down direction) are gradually decreased from up to down.

As above, it is possible to change the inclination angle of the chassis 7 by changing the height of the seats 822 in the longitudinal direction of the insertion portion 87 of the fixture 8.

Then, it is possible to fix the fixture 8 for which the degree of difference of the heights of the upper and lower seats 822 is changed at the desired positions of the chassis 7 according to the model and change the inclination angle of the chassis 7.

### Embodiment 4

In Embodiment 4 of the present disclosure, the inclination angle of the chassis 7 is adjusted at the screw insertion hole 81 side and not at the pin insertion hole 82 side of the fixture 8.

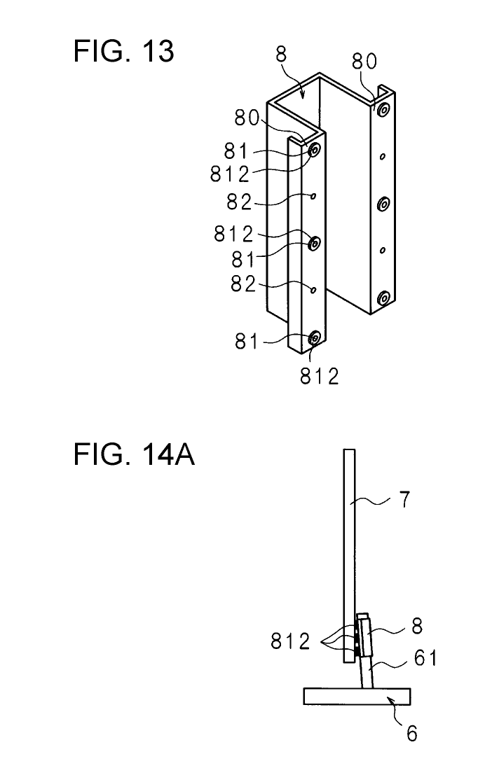

FIG. 13 is a perspective view illustrating a state in which the fixture 8 according to Embodiment 4 is viewed from the rear side.

As shown in FIG. 13, a seat 812 with a disc shape is provided around the screw insertion hole 81 of the abutting plate portion 80 of the fixture 8.

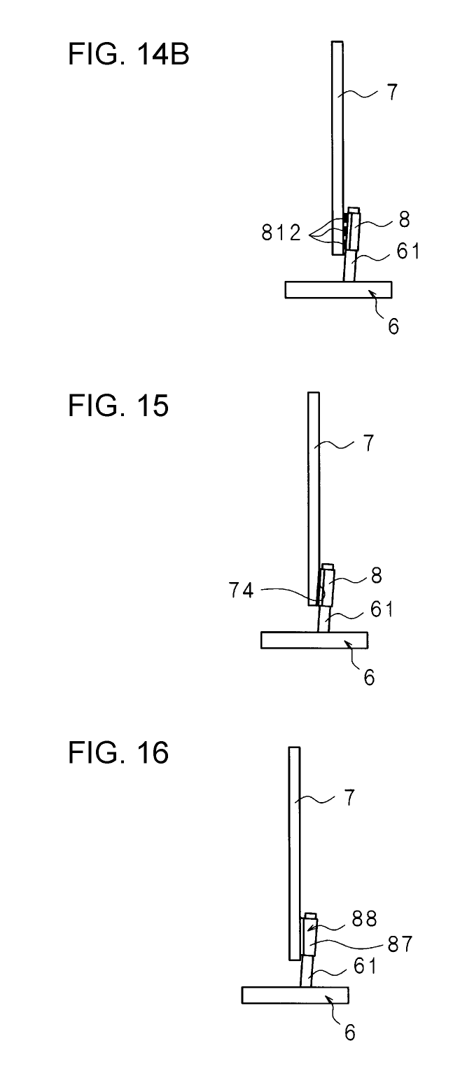

FIGS. 14A and 14B are diagrams for describing a method in which the inclination angle of the chassis 7 is adjusted by changing the height of the seat 812.

As shown in FIG. 14A, in a case where the support shaft 61 of the stand 6 is at the forward-bent posture, the vertical direction of the chassis 7 substantially matches the direction perpendicular to the foot portion 62 by the height of the seat 812 at the lower side being higher than at the upper side, that is, by configuring such that the heights of the seats 812 in the vertical direction (up and down direction) are gradually increased from up to down.

In a case where the support shaft 61 is provided so as to substantially match the perpendicular direction, it is possible to set the chassis 7 to a rearward-bent posture by the height of the seat 812 at the lower side being higher than at the upper side.

As shown in FIG. 14B, in a case where the support shaft 61 of the stand 6 is at the rearward-bent posture, the vertical direction of the chassis 7 substantially matches the direction perpendicular to the foot portion 62 by the height of the seat 812 at the upper side being higher than at the lower side, that is, by configuring such that the heights of the seats 812 in the vertical direction (up and down direction) are gradually decreased from up to down.

As above, it is possible to change the inclination angle of the chassis 7 by gradually changing the height of the seats 812 in the vertical direction of the chassis 7.

Then, it is possible to fix the fixture 8 for which the degree of difference of the heights of the upper and lower seats 812 is changed at the desired positions of the chassis 7 according to the model and change the inclination angle of the chassis 7.

### Embodiment 5

In Embodiment 5 of the present disclosure, the inclination angle of the chassis 7 is adjusted by inclining a part on the lower side of the bottom surface of the chassis 7.

FIG. 15 is a diagram for describing a method in which the inclination angle of the chassis 7 is adjusted by inclining a part on the lower side of the bottom surface of the chassis 7.

As shown in FIG. 15, in a case where the support shaft 61 of the stand 6 is at the rearward-bent posture, the vertical direction of the chassis 7 substantially matches the direction perpendicular to the foot portion 62 by inclining the part on the lower side of the bottom surface of the chassis 7 such that the width becomes narrow from up to down viewing the side surface.

As above, it is possible to change the inclination angle of the chassis 7 by changing the width of the chassis 7.

Then, it is possible to fix the fixture 8 at the desired positions of the chassis 7 according to the model and change the inclination angle of the chassis 7 by changing the degree of inclination of the chassis 7 in the lateral direction of the chassis 7.

### Embodiment 6

In Embodiment 6 of the present disclosure, the inclination angle of the chassis 7 is adjusted by changing the height of the fixture 88.

FIG. 16 is a diagram for describing a method in which the inclination angle of the chassis 7 is adjusted by changing the height of the fixture 88.

In the fixture 88 of the present embodiment, the height of the insertion portion 87 (width of the insertion portion 87 when viewing the side surface thereof) is lowered from up to down. Accordingly, as shown in FIG. 16, in a case where the support shaft 61 of the stand 6 is at the rearward-bent posture, the vertical direction of the chassis 7 substantially matches the direction perpendicular to the foot portion 62.

As above, it is possible to change the inclination angle of the chassis 7 by changing the height of the insertion portion 87.

Then, it is possible to fix the fixture 8 for which the degree of difference of the heights of the insertion portion 87 is changed at the desired positions of the chassis 7 according to the model and change the inclination angle of the chassis 7.

As above, the display device (1) according to the present disclosure is provided with the display portion (2) that includes the display panel (21) which displays a video, the holding body (7) that holds the display portion, the stand (6) that supports the holding body, the fixture (8) for attaching the stand to the holding body, and a plurality of fixing portions (71, 72, 812, 822) that are interposed between the fixture and the holding body and fix the fixture to the holding body, in which in a case where at least some fixing portions fix the fixture to the holding body, the holding body has a predetermined angle with respect to the fixture.

In the present disclosure, in a case where at least one of the fixing portions fixes the fixture to the holding body, it is possible to set the angle between the fixture and the holding body to the desired angle and it is possible to set the inclination angle of the holding body to the desired value.

Accordingly, it allows commonality of the fixing structure of the holding body having the display portion and the stand without lowering the product outer appearance quality.

In the display device according to the present disclosure, lengths of the fixing portions in a direction in which the fixture and the holding body face each other are different.

In the present disclosure, since the lengths of the fixing portions in a direction in which the fixture and the holding body face each other are different, it is possible to easily set the angle between the fixture and the holding body to the desired angle and it is possible to set the inclination angle of the holding body to the desired value.

In the display device according to the present disclosure, a plurality of the fixing portions are arranged side by side in a vertical direction of the display portion, and the lengths gradually change between the fixing portions.

In the present disclosure, since the lengths of the fixing portions in the vertical direction of the display portion are configured so as to gradually change, it is possible to easily set the inclination angle of the holding body to the desired value.

In the display device according to the present disclosure, a plurality of the fixing portions are arranged side by side in a lateral direction of the display portion, and the degrees of difference of the lengths of the fixing portions in the vertical direction are different in the lateral direction.

In the present disclosure, it is possible to fix the fixture that has the same or different inclination angle with respect to the vertical direction at the desired position of the holding body and set the inclination angle of the holding body to the desired angle.

In the display device according to the present disclosure, the plurality of the fixing portions (71) are provided in the holding body, each of the fixing portions has the hole (711) that has the female screw and the seat (712) that is provided around the hole, the heights of the seats are different in at least some fixing portions, and the fixture has the screw insertion hole (81) for a male screw (84) to be inserted through and screwed into the female screw.

In the present disclosure, it is possible to easily set the inclination angle of the holding body to the desired value by configuring the lengths of the fixing portions to be different in the vertical direction of the holding body. In addition, it is possible to attach the different stands at the desired position and obtain the desired inclination angle of the holding body by configuring the lengths of the fixing portions to be different in the lateral direction of the holding body.

In the display device according to the present disclosure, the fixing portions (72) are provided in the holding body, each of the fixing portions has the pin (721) and the seat (722) that is provided around the pin, the heights of the seats are different in at least some fixing portions, and the fixture has the pin insertion hole (82) into which the pin is inserted and positionally aligned.

In the present disclosure, it is possible to easily change the length by changing the height of the seat.

In the display device according to the present disclosure, the fixing portions are provided in the fixture, each of the fixing portions has the screw insertion hole (81) and the seat (812) that is provided around the screw insertion hole, the heights of the seats are different in at least some fixing portions, and the female screw into which the male screw (84) that is inserted into the screw insertion hole is screwed is provided in the holding body.

In the present disclosure, it is possible to easily change the length by changing the height of the seat.

In the display device according to the present disclosure, the fixing portions are provided in the fixture, each of the fixing portions has the pin insertion hole (82) and the seat (822) that is provided around the pin insertion hole, the heights of the seats are different in some fixing portions, and the pin (721) that is inserted into the pin insertion hole is provided in the holding body.

In the present disclosure, it is possible to easily change the length by changing the height of the seat.

The display device (1) according to the present disclosure is provided with the display portion (2) that includes the display panel (21) which displays a video, the holding body (7) that holds the display portion, the stand (6) that supports the holding body, and the fixture (8) for attaching the stand to the holding body, in which the holding body is a box shape, and is disposed in vertical posture, and a part of the bottom surface is inclined.

In the present disclosure, it is possible to attach the different stands to the desired position and obtain the desired inclination angle of the holding body by changing the inclination angle of the bottom surface of the holding body in the lateral direction of the holding body.

The display device (1) according to the present disclosure is provided with the display portion (2) that includes the display panel (21) which displays a video, the holding body (7) that holds the display portion, the stand (6) that supports the holding body, and the fixture (8) for attaching the stand to the holding body, in which the stand is provided with the foot portion (62) and the support shaft (61) that extends from the foot portion, the cross section of the fixture is a U shape, the fixture is provided with the insertion portion (87) that extends in a direction centered on the support shaft and in which the support shaft is inserted, and the width of the insertion portion viewed from the side surface is different in the shaft direction.

In the present disclosure, it is possible to use the fixture that has a different degree of change of width of the insertion portion viewed from the side surface, attach the stand to the desired position, and obtain the desired inclination angle of the holding body.

The television receiver (1) according to the present disclosure is provided with any display device described above, and a receiver (11) that receives a television broadcast, in which a video is displayed on the display device based on the television broadcast that is received by the receiver.

In the present disclosure, it is possible to easily set the desired inclination angle of the display portion in each model.

The present disclosure is not limited to the content of the embodiments described above and various modifications are possible in the range indicated in the claims. That is, embodiments obtained by combining the appropriately modified technical means in a range indicated in the claims are included in the technical scope of the present disclosure.

For example, in the embodiments, description is made of a case where the present disclosure is applied to a liquid crystal TV receiver, but is not limited thereto, and it is possible to apply the present disclosure to another TV receiver such as an organic ELTV receiver. In addition, it is also possible to combine the configurations of two or more embodiments.

It is to be noted that, as used herein and in the appended claims, the singular forms “a”, “an”, and “the” include plural referents unless the context clearly dictates otherwise.

It is to be noted that the disclosed embodiment is illustrative and not restrictive in all aspects. The scope of the present invention is defined by the appended claims rather than by the description preceding them, and all changes that fall within metes and bounds of the claims, or equivalence of such metes and bounds thereof are therefore intended to be embraced by the claims.

1-8. (canceled)

9. A display device comprising:
a display portion that includes a display panel which displays a video;
a holding body that holds the display portion;
a stand that supports the holding body;
a fixture for attaching the stand to the holding body; and
a plurality of fixing portions that are interposed between the fixture and the holding body and fix the fixture to the holding body,
wherein in a case where at least some fixing portions fix the fixture to the holding body, the holding body has a predetermined angle with respect to the fixture.

10. The display device according to claim 9,
wherein lengths of the fixing portions in a direction in which the fixture and the holding body face each other are different.

11. The display device according to claim 10,
wherein the plurality of the fixing portions are arranged side by side in a vertical direction of the display portion, and
the lengths gradually change between the fixing portions.

12. The display device according to claim 11,
wherein the plurality of the fixing portions are arranged side by side in a lateral direction of the display portion, and
the degrees of difference of the lengths of the fixing portions in the vertical direction are different in the lateral direction.

13. The display device according to claim 10,
wherein the plurality of the fixing portions are provided in the holding body,
each of the fixing portions has a hole that has a female screw and a seat that is provided around the hole and the heights of the seats are different in at least some fixing portions, and
the fixture has a screw insertion hole for a male screw to be inserted through and screwed into the female screw.

14. The display device according to claim 11,
wherein the plurality of the fixing portions are provided in the holding body,
each of the fixing portions has a hole that has a female screw and a seat that is provided around the hole and the heights of the seats are different in at least some fixing portions, and
the fixture has a screw insertion hole for a male screw to be inserted through and screwed into the female screw.

15. The display device according to claim 10,
wherein the fixing portions are provided in the holding body,
each of the fixing portions has a pin and a seat that is provided around the pin, and the heights of the seats are different in at least some fixing portions, and
the fixture has a pin insertion hole into which the pin is inserted and positionally aligned.

16. The display device according to claim 11,
wherein the fixing portions are provided in the holding body,
each of the fixing portions has a pin and a seat that is provided around the pin, and the heights of the seats are different in at least some fixing portions, and
the fixture has a pin insertion hole into which the pin is inserted and positionally aligned.

17. The display device according to claim 13,
wherein the fixing portions are provided in the holding body,
each of the fixing portions has a pin and a seat that is provided around the pin, and the heights of the seats are different in at least some fixing portions, and
the fixture has a pin insertion hole into which the pin is inserted and positionally aligned.

18. The display device according to claim 10,
wherein the fixing portions are provided in the fixture,
each of the fixing portions has a screw insertion hole and a seat that is provided around the screw insertion hole, and the heights of the seats are different in at least some fixing portions, and
a female screw into which a screw that is inserted into the screw insertion hole is screwed is provided in the holding body.

19. The display device according to claim 11,
wherein the fixing portions are provided in the fixture,
each of the fixing portions has a screw insertion hole and a seat that is provided around the screw insertion hole, and the heights of the seats are different in at least some fixing portions, and
a female screw into which a screw that is inserted into the screw insertion hole is screwed is provided in the holding body.

20. The display device according to claim 10,
wherein the fixing portions are provided in the fixture,
each of the fixing portions has the pin insertion hole and the seat that is provided around the pin insertion hole, the heights of the seats are different in some fixing portions, and the pin that is inserted into the pin insertion hole is provided in the holding body.

21. The display device according to claim 11,
wherein the fixing portions are provided in the fixture,
each of the fixing portions has the pin insertion hole and the seat that is provided around the pin insertion hole, the heights of the seats are different in some fixing portions, and the pin that is inserted into the pin insertion hole is provided in the holding body.

22. A display device comprising:
a display portion that includes the display panel which displays a video;
a holding body that holds the display portion;
a stand that supports the holding body; and
a fixture for attaching the stand to the holding body, wherein the holding body is a box shape, and is disposed in vertical posture, and a part of the bottom surface is inclined.

23. A display device comprising:
a display portion that includes the display panel which displays a video;
a holding body that holds the display portion;
a stand that supports the holding body; and
a fixture for attaching the stand to the holding body, wherein the stand is provided with the foot portion and the support shaft that extends from the foot portion, the cross section of the fixture is a U shape, the fixture is provided with the insertion portion which extends in a direction centered on the support shaft and in which the support shaft is inserted, and the width of the insertion portion viewed from the side surface is different in the shaft direction.

24. A television receiver comprising:
the display device according to claim 9, and
a receiver that receives a television broadcast,
wherein a video is displayed on the display device based on the television broadcast that is received by the receiver.

25. A television receiver comprising:
the display device according to claim 10, and
a receiver that receives a television broadcast,
wherein a video is displayed on the display device based on the television broadcast that is received by the receiver.

26. A television receiver comprising:
the display device according to claim 11, and
a receiver that receives a television broadcast,
wherein a video is displayed on the display device based on the television broadcast that is received by the receiver.

27. A television receiver comprising:
the display device according to claim 13, and
a receiver that receives a television broadcast,
wherein a video is displayed on the display device based on the television broadcast that is received by the receiver.

28. A television receiver comprising:
the display device according to claim 18, and
a receiver that receives a television broadcast,
wherein a video is displayed on the display device based on the television broadcast that is received by the receiver.
